(19) United States
(12) Patent Application Publication
(10) Pub. No.: US 2009/0175009 A1
(43) Pub. Date: Jul. 9, 2009

(54) Hook structure and device having hook structure

(76) Inventor: Wei-Han Pu, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/314,532

(22) Filed: Dec. 12, 2008

(30) Foreign Application Priority Data
Jan. 9, 2008 (TW) 97200541

(51) Int. Cl. H05K 7/00

(52) U.S. Cl. 361/760

(57) ABSTRACT

A hook structure for combining an element on a print circuit board tightly includes a body, at least one extension and at least one hooking portion. The body is fixed to the element. The extension extends from the bottom of the body. The hooking portion is provided on one end of the extension. One side of the hooking portion is formed with a hooking surface and a horizontal plane. One end of the hooking surface is connected to the horizontal plane. The height difference between two ends of the hooking surface is larger than the distance between the horizontal plane and the print circuit board. The hooking portion is hooked to the print circuit board. Via this arrangement, the element can be positioned and fixed on the print circuit board, so that the device can be combined on the print circuit board tightly.

### BACKGROUND OF THE INVENTION

1. Field of the Invention

The present invention relates to a hook structure, and in particular to a hook structure for hooking and positioning and a device having such a hook structure.

2. Description of Related Art

Please refer to FIGS. 1 and 2, which show a conventional hook structure. The hook structure 10a is used to fix an aluminum plate 20a on a print circuit board 30a, thereby preventing the print circuit board 30a from bending due to heat when the print circuit board 30a is processed in a tin furnace. The hook structure 10a is made of copper with tin plated, which includes a body 11a and an extension 12a. The body 11a is fixed to one side surface of the aluminum plate 20a. The extension 11a extends downwards from the bottom of the body 11a.

When the aluminum plate 20a is disposed on the print circuit board 30a, the extension 12a of the hook structure 10a is inserted into a through-hole 31a of the print circuit board 30a. In order to combine the aluminum plate 20a on the print circuit board 30a tightly, a common way is to twist a portion of the extension 12a passing through the through-hole 31a on the other surface of the print circuit board 30a. The twisted portion of the extension 12a will form a stopping portion 13a for stopping the print circuit board 30a. Then, the stopping portion 13a is soldered for better fixation.

However, the above process wastes a lot of labors and working hours. Since this process involves a plurality of steps, the manufacturing rate becomes slower, and thus the production cost is increased undesirably.

Consequently, because of the above limitation resulting from the technical design of prior art, the inventor strives via real world experience and academic research to develop the present invention, which can effectively improve the limitations described above.

### SUMMARY OF THE INVENTION

The object of the present invention is to provide a hook structure and a device having a hook structure. The hook structure is used for positioning and locking when the device is inserted into a print circuit board. Via this arrangement, the labors, working hours and cost can be reduced while the manufacturing rate is increased. Also, the hook structure allows the device to be combined on the print circuit board tightly, thereby preventing the print circuit board from bending when it is processed in a tin furnace.

In order to achieve the above objects, the present invention provides a hook structure. The hook structure is used to combine an element on a print circuit board tightly, which includes a body fixed to the element; at least one extension extending from the bottom of the body; and at least one hooking portion provided on one end of the extension, one side of the hooking portion being formed with a hooking surface and a horizontal plane, one end of the hooking surface being connected to the horizontal plane, the height difference between two ends of the hooking surface being larger than the distance between the horizontal plane and the print circuit board, the hooking portion being hooked to the print circuit board.

The present invention further provides a device having the hook structure. The hook structure is used to combine the device on a print circuit board tightly. The device includes a casing and at least one hook structure. The hook structure has a body, an extension and a hooking portion. The body is fixed to the casing. The extension extends from the bottom of the body. The hooking portion is provided on one end of the extension. One side of the hooking portion is formed with a hooking surface and a horizontal plane. One end of the hooking surface is connected to the horizontal plane. The height difference between two ends of the hooking surface is larger than the distance between the horizontal plane and the print circuit board. The hooking portion is hooked to the circuit board.

The present invention has advantageous features as follows. The two hooking portions are provided on free ends of the two extensions. One side of each hooking portion is formed with the hooking surface and the horizontal plane. The lower end of the hooking surface is connected to the horizontal plane. The height difference between two ends of the hooking surface is larger than the distance between the horizontal plane and the print circuit board. When the device having the hook structure is inserted on the print circuit board, the two extensions are compressed by the through-hole of the print circuit board to generate an elastic recovering force. Due to this elastic recovering force, the two hooking portions abut the print circuit board to generate a reaction force for pulling downwards the print circuit board. As a result, the device can be combined on the print circuit board tightly, thereby preventing the print circuit board from bending when it is processed in the tin furnace. With a simple structure, the hook structure is inserted into the through-hole to position and secure the device immediately, so that the labors, working hours and cost can be reduced and the manufacturing rate can be increased.

In order to further understand the characteristics and technical contents of the present invention, a detailed description relating thereto will be made with reference to the accompanying drawings. However, the drawings are illustrative only, but not used to limit the scope of the present invention.

### BRIEF DESCRIPTION OF THE DRAWINGS

FIG. 1 is a schematic view showing a conventional hook structure combining two elements;

FIG. 2 is a side view showing the conventional hook structure combining two elements;

FIG. 3 is a perspective view showing the hook structure of the present invention;

FIG. 4 is a perspective view showing the hook structure of the present invention combining two elements;

FIG. 5 is a partially enlarged cross-sectional view of the hook structure of the present invention;

FIG. 6 is a perspective view showing the device having the hook structure of the present invention;

FIG. 7 is a perspective view showing the device having the hook structure of the present invention being disposed on a print circuit board;

FIG. 8 is a perspective view showing the hook structure in accordance with the second embodiment of the present invention;

FIG. 9 is a perspective view showing the hook structure in accordance with the third embodiment of the present invention; and

FIG. 10 is a perspective view showing the hook structure in accordance with the fourth embodiment of the present invention.

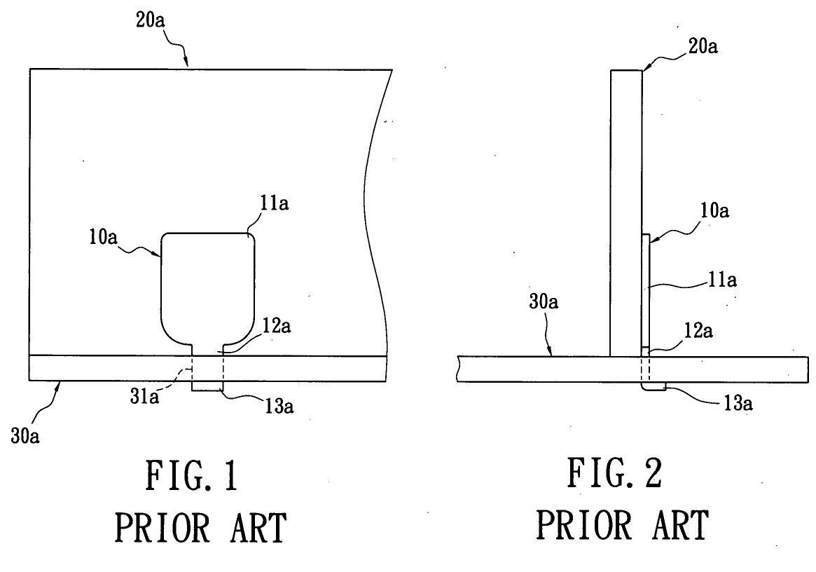

### DETAILED DESCRIPTION OF PREFERRED EMBODIMENTS

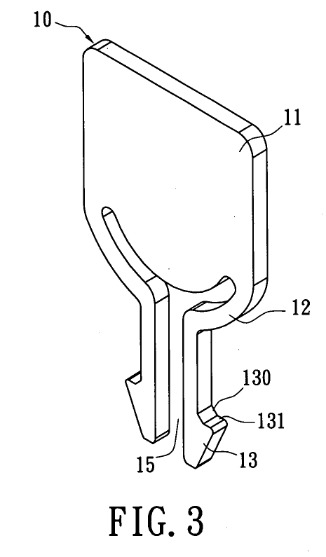

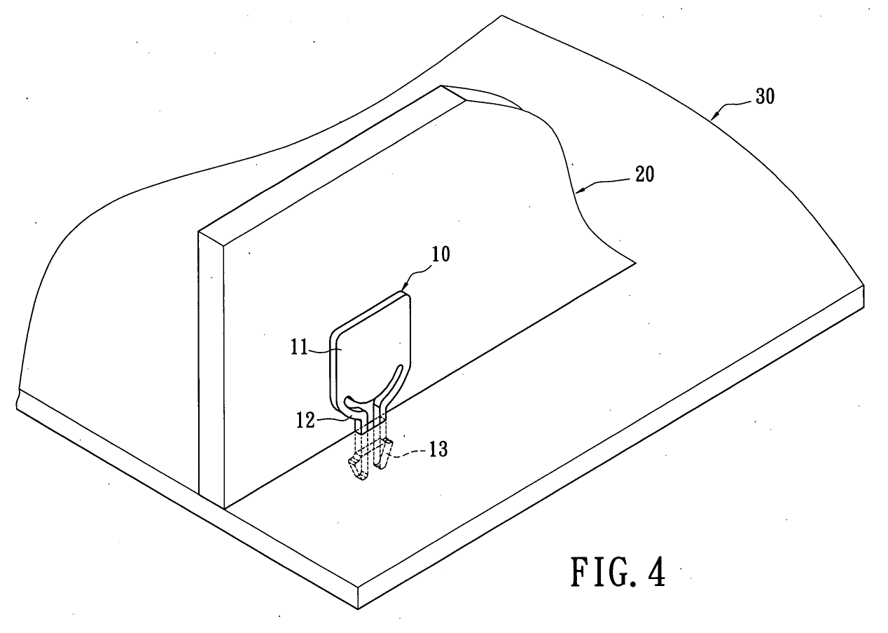

Please refer to FIGS. 3 to 5. The present invention provides a hook structure. The hook structure 10 is an elastic body for combining an element 20 on a print circuit board 30 tightly. In the present embodiment, the element 20 is an aluminum plate, but it may be other elements. The hook structure 10 includes a body 11, at least one extension 12 and at least one hooking portion 13. The body 11 is substantially formed into a rectangular sheet. The body 11 can be fixedly disposed on the element 20.

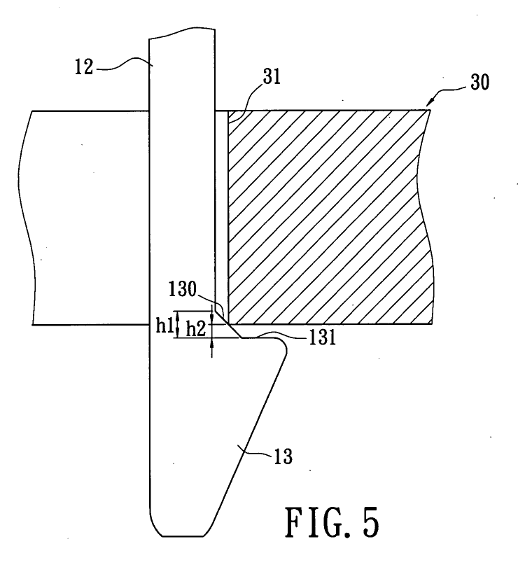

In the present embodiment, the hook structure 10 has two extensions 12. The two extensions 12 are formed by bending downwards and extending from the bottom of the body 11 adjacent to both sides thereof. A Y-shaped first opening 15 is formed between the two extensions 12. The two extensions 12 can be inserted into through-holes 31 of a print circuit board 30 (FIG. 5).

In the present embodiment, the free end of each of the two extensions 12 is provided with a hooking portion 13. The hooking portion 13 is formed into a hook. One side of each hooking portion 13 is formed with a hooking surface 130 and a horizontal plane 131. The hooking surface, 130 is a slope. The lower end of the hooking surface 130 is connected to the horizontal plane 131. The height difference h1 between two ends of the hooking surface 130 is larger than the distance h2 between the horizontal plane 131 and the print circuit board 30.

When the two hooking portions 13 are hooked to the print circuit board 30, the two extensions 12 are compressed by the through-holes 31 to generate an elastic recovering force. Due to the elastic recovering force, the two hooking surfaces 130 can abut the print circuit plate 30 to generate a reaction force, thereby pulling downwards the element 20. In this way, the element 20 can be combined tightly on the print circuit board 30.

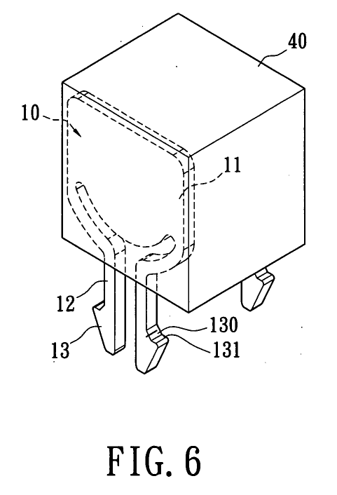

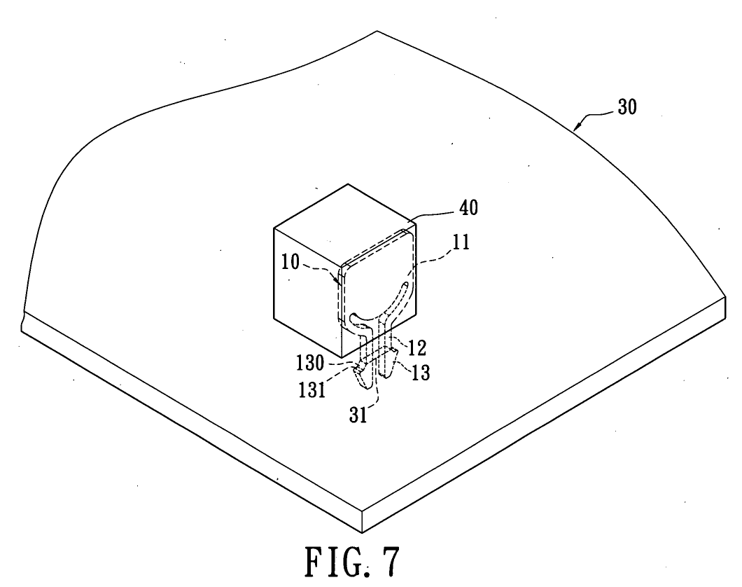

Please refer to FIGS. 6 and 7. The present invention further provides a device having the hook structure. The hook structure 10 allows the device to be combined tightly on a circuit board 30. The device (e.g. an electrical connector or heat sink) includes a casing 40 and at least one hook structure 10. The interior of the casing 40 has a plurality of elements and electronic components (not shown), thereby maintaining the operation of the device.

The difference between the present -embodiment and the previous embodiment lies in that: the device has two hook structures 10, but the number of the hook structure is not limited thereto. The body 11 is fixedly disposed in the casing 40 of the device. The two extensions 12 can be inserted into the through-hole 31 of the print circuit board 30. When the two hooking portions 13 are hooked to the print circuit board 30, the two extensions 12 are compressed by the through-hole 31 to generate an elastic recovering force. Due to the elastic recovering force, the two hooking surfaces 130 abut the print circuit board 30 to generate a reaction force for pulling downwards the casing 40 of the device. In this way, the device can be combined on the print circuit board 30 tightly.

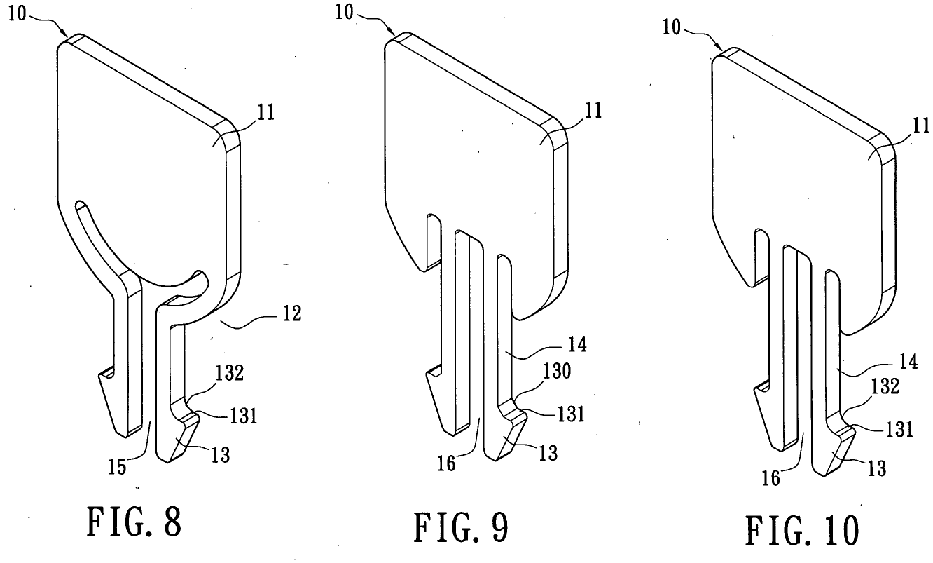

Please refer to FIG. 8, which is a perspective view showing the second embodiment of the hook structure of the present invention. The difference between the present embodiment and the previous embodiment lies in that: one side of each of the two hooking portions 13 is formed with a hooking surface 132. The hooking surface 132 is a curved surface.

Please refer to FIG. 9, which is a perspective view showing the third embodiment of the hook structure of the present invention. The difference between the present embodiment and the first embodiment (FIG. 3) lies in that: the bottom of the body 11 extends downwards to form two straight extensions 14. Between the two extensions 14, a straight second opening 16 is formed between the extension 14 and the body 11.

Please refer to FIG. 10, which is a perspective view showing the fourth embodiment of the hook structure of the present invention. The difference between the present embodiment and the third embodiment lies in that: one side of each of the two hooking portions 13 is formed with a hooking surface 132. The hooking surface 132 is a curved surface.

In the present invention, the two hooking portions 13 are provided on the free ends of the two extensions 12. One side of each of the two hooking portions 13 is formed with the hooking surface 130 and the horizontal plane 131. The lower end of the hooking surface 130 is connected to the horizontal plane 131. The height difference between two ends of the hooking surface 130 is larger than the distance between the horizontal plane 131 and the print circuit board 30. Via this arrangement, when the device having hook structure 10 is inserted onto the print circuit board 30, the two extensions 12 are compressed by the through-hole 31 of the print circuit board 30 to generate an elastic recovering force. Due to the elastic recovering force, the two hooking surfaces 130 can abut the print circuit plate 30 to generate a reaction force, thereby pulling downwards the casing 40. In this way, the device can be combined tightly on the print circuit board 30, thereby preventing the print circuit board 30 from bending when it is processed in the tin furnace. With a simple structure, the hook structure 10 can be inserted into the through-hole 31 easily to position and secure the device immediately, so that the labors, working hours and cost can be reduced and the manufacturing rate can be increased.

While the present invention has been described in terms of what is presently considered to be the most practical and preferred embodiments, it is to be understood that the present invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A hook structure for combining an element on a print circuit board tightly, comprising:
a body fixed to the element;
at least one extension extending from the bottom of the body; and
at least one hooking portion provided on one end of the extension, one side of the hooking portion being formed with a hooking surface and a horizontal plane, one end of the hooking surface being connected to the horizontal plane, the height difference between two ends of the hooking surface being larger than the distance between the horizontal plane and the print circuit board, the hooking portion being hooked to the print circuit board.

2. The hook structure according to claim 1, wherein the hooking surface is a slope.

3. The hook structure according to claim 1, wherein the hooking surface is a curved surface.

4. The hook structure according to claim 1, wherein the extension extends straightly from the bottom of the body.

5. The hook structure according to claim 1, wherein the extension is formed by bending and extending from the bottom of the body.

6. A device having a hook structure, the hook structure being used to combine the device on a print circuit board tightly, the device comprising:
a casing, and
at least one hook structure having a body, an extension and a hooking portion, the body being fixed to the casing, the extension extending from the bottom of the body, the hooking portion being provided on one end of the extension, one side of the hooking portion being formed with a hooking surface and a horizontal plane, one end of the hooking surface being connected to the horizontal plane, the height difference between two ends of the hooking surface being larger than the distance between the horizontal plane and the print circuit board, the hooking portion is hooked to the print circuit board.

7. The device having hook structure according to claim 6, wherein the hooking surface is a slope.

8. The device having hook structure according to claim 6, wherein the hooking surface is a curved surface.

9. The device having hook structure according to claim 6, wherein the extension extends straightly from the bottom of the body.

10. The device having hook structure according to claim 6, wherein the extension is formed by bending and extending from the bottom of the body.
